(19) United States
(12) Patent Application Publication
(10) Pub. No.: US 2024/0329123 A1
(43) Pub. Date: Oct. 3, 2024

(54) SEMICONDUCTOR DEVICE AND TEST METHOD

(71) Applicant: LAPIS Technology Co., Ltd., Yokohama (JP)

(72) Inventor: Hirokazu MIYAZAKI, Yokohama (JP)

(73) Assignee: LAPIS Technology Co., Ltd., Yokohama (JP)

(21) Appl. No.: 18/607,535

(22) Filed: Mar. 17, 2024

(30) Foreign Application Priority Data
Mar. 31, 2023 (JP) 2023-057157

(51) Int. Cl. G01R 31/28; H03L 7/085

(52) U.S. Cl. CPC G01R 31/2884; H03L 7/085

(57) ABSTRACT

The disclosure provides a semiconductor device including a plurality of reception circuit blocks each individually receiving a data signal, performing predetermined signal processing for the received data signal, and receiving a test mode signal for instructing a normal operation or a test operation. Each of the plurality of reception circuit blocks includes a PLL circuit generating a clock signal phase-synchronized with a data signal received by itself; a first selector selecting, based on the test mode signal, one of the clock signal generated by the PLL circuit of a different reception circuit block other than a reception circuit block of itself of the plurality of reception circuit blocks and the clock signal generated by the PLL circuit of the reception circuit block of itself, and a signal processing circuit performing the predetermined signal processing in synchronization with the clock signal selected by the first selector.

### CROSS-REFERENCE TO RELATED APPLICATION

This application claims priority under 35 USC 119 from Japanese Patent application No. 2023-057157 filed on Mar. 31, 2023, the disclosure of which is incorporated by reference herein.

### BACKGROUND

### Technical Field

The disclosure relates to a semiconductor device and a test method for the semiconductor device.

### Description of Related Art

In a test of semiconductor integrated circuit (IC) chips performed before product shipment, an LSI tester is first connected to a semiconductor IC chip to be tested. Next, using this LSI tester, a testing signal for actually operating a circuit group formed on the semiconductor IC chip at a rated frequency according to specifications is input to the semiconductor IC chip. At this time, output results output through operation of the semiconductor IC chip in response to the testing signal are taken in by the LSI tester, and the output results are subsequently compared with an expected value so as to judge the quality of the semiconductor IC chip.

Incidentally, in recent years, as the resolution of images has increased, operation frequencies of image processing circuits have become higher, and when semiconductor IC chips including such an image processing circuit are tested, a high-frequency compatible LSI tester is required.

For example, when testing semiconductor IC chips including an image processing circuit that operates in synchronization with an external clock signal received through an input terminal, a high-frequency compatible LSI tester capable of supplying a high-frequency clock signal to a semiconductor IC chip as a testing external clock signal is required.

However, such high-frequency compatible LSI testers are expensive, which leads to increase in manufacturing costs.

Hence, a semiconductor integrated circuit having a semiconductor IC chip provided with a phase-locked loop (PLL) circuit generating a testing clock signal having a rated frequency according to specifications and a switching circuit selectively supplying one of this testing clock signal and the foregoing external clock signal to an internal circuit has been proposed (for example, refer to Japanese Patent Laid-Open No. 2002-196046).

When testing such semiconductor integrated circuits, an LSI tester supplies a testing data signal to a semiconductor integrated circuit while supplying a clock signal which can be self-generated and has a frequency lower than a rated frequency according to specifications to the semiconductor integrated circuit as an external clock signal. At this time, the LSI tester controls the switching circuit such that an external clock signal is supplied to the internal circuit. Here, if a testing data signal is taken into the semiconductor integrated circuit in response to the external clock signal, the LSI tester controls the switching circuit such that a testing clock signal which is generated by the PLL circuit and has a rated frequency is supplied to the internal circuit in place of the external clock signal.

Accordingly, the internal circuit performs an operation based on a testing data signal using a testing clock signal having a rated frequency according to specifications and outputs output results from the operation to the LSI tester.

However, the semiconductor integrated circuit described in Japanese Patent Laid-Open No. 2002-196046 requires a PLL circuit simply for test purposes and a circuit for generating a reference clock to be supplied to the PLL circuit or an input terminal for externally inputting the reference clock, resulting in a problem of increase in circuit size.

Hence, the disclosure provides a semiconductor device in which increase in circuit size is curbed and a high-speed operation test can be performed without depending on a frequency that can be applied to an LSI tester, and a test method therefor.

### SUMMARY

A semiconductor device according to the disclosure includes a plurality of reception circuit blocks each individually receiving a data signal, performing predetermined signal processing for the received data signal, and receiving a test mode signal for instructing a normal operation or a test operation. Each of the plurality of reception circuit blocks includes a phase-locked loop (PLL) circuit generating a clock signal phase-synchronized with a data signal received by itself; a first selector selecting, based on the test mode signal, among the plurality of reception circuit blocks, one of the clock signal generated by the PLL circuit of a different reception circuit block other than a reception circuit block of itself and the clock signal generated by the PLL circuit of the reception circuit block of itself; and a signal processing circuit performing the predetermined signal processing in synchronization with the clock signal selected by the first selector.

In addition, a test method for the semiconductor device according to the disclosure is used for testing the semiconductor device. The test method has a step of supplying the test mode signal indicating the test operation to the PLL circuit of each of the plurality of reception circuit blocks and the first selector in response to a test signal prompting execution of a test; a step of supplying a testing data signal to the signal processing circuit of each of the plurality of reception circuit blocks; and a step of judging a quality by sequentially taking in output results output from the signal processing circuit of each of the plurality of reception circuit blocks and comparing the output results with an expected value.

### BRIEF DESCRIPTION OF THE DRAWINGS

FIG. 1 is a block diagram showing a constitution of a data reception circuit 100 formed in a semiconductor chip serving as a semiconductor device according to the disclosure.

FIG. 2 is a block diagram showing an internal constitution of a receiver 11 and a selection circuit 12 included in a reception circuit block 10_1.

FIG. 3 is a block diagram showing an internal constitution of a PLL circuit 112.

FIG. 4 is a flowchart showing a test control flow.

### DESCRIPTION OF THE EMBODIMENT

In the disclosure, during a test operation, the frequency of a clock signal generated by the PLL circuit included in each of the reception circuit blocks is switched to a frequency higher than that during a normal operation. Further, in each of the reception circuit blocks, the signal processing circuit of itself is operated in response to a clock signal generated by the PLL circuit of a different reception circuit block other than that of itself. Accordingly, operation of the signal processing circuit can be tested using an internally generated high-frequency clock signal without providing an oscillation circuit generating a clock signal having a frequency higher than the frequency that can be applied to an LSI tester simply for test purposes.

Thus, according to the disclosure, it is possible to curb increase in circuit size and perform a high-speed operation test for semiconductor devices without depending on a frequency that can be applied to an LSI tester.

Hereinafter, Examples of the disclosure will be described in detail with reference to the drawings.

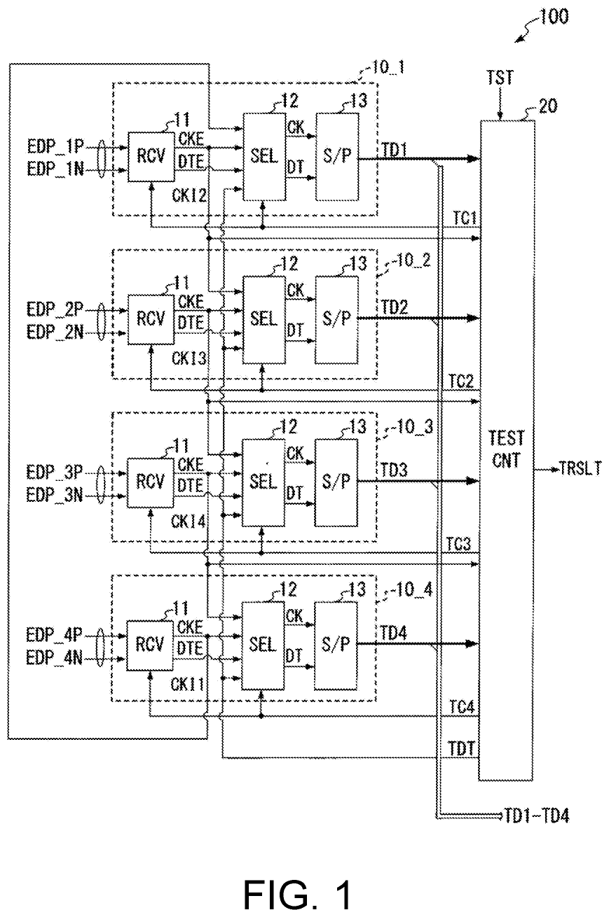

FIG. 1 is a block diagram showing a constitution of a data reception circuit 100 formed in a semiconductor chip serving as a semiconductor device according to the disclosure.

The data reception circuit 100 includes reception circuit blocks 10_1 to 10_4 (four systems) and a test control circuit 20.

The reception circuit blocks 10_1 to 10_4 individually receive differential serial data signals of the following four systems, which are binary data signals in a serial form (logical level 0 or 1) converted into differential signals.
Differential serial data signals (EDP_1P and EDP_1N)
Differential serial data signals (EDP_2P and EDP_2N)
Differential serial data signals (EDP_3P and EDP_3N)
Differential serial data signals (EDP_4P and EDP_4N)

Further, the reception circuit blocks 10_1 to 10_4 respectively convert these differential serial data signals of four systems into pieces of data in an 8-bit parallel form, for example, and output them as reception data TD1 to the reception data TD4, respectively. The reception circuit blocks 10_1 to 10_4 supply the reception data TD1 to the reception data TD4 to a main signal processing circuit (not shown) and the test control circuit 20 formed on this semiconductor chip. This main signal processing circuit performs various kinds of signal processing conducting functions of this semiconductor chip based on the reception data TD1 to the reception data TD4.

As shown in FIG. 1, each of the reception circuit blocks 10_1 to 10_4 has the same internal constitution, namely, includes a receiver 11, a selection circuit 12, and a serial-parallel conversion circuit 13 (which will hereinafter be referred to as an S/P conversion circuit 13).

Hereinafter, the reception circuit block 10_1 is extracted from the reception circuit blocks 10_1 to 10_4, and the internal constitution thereof will be described.

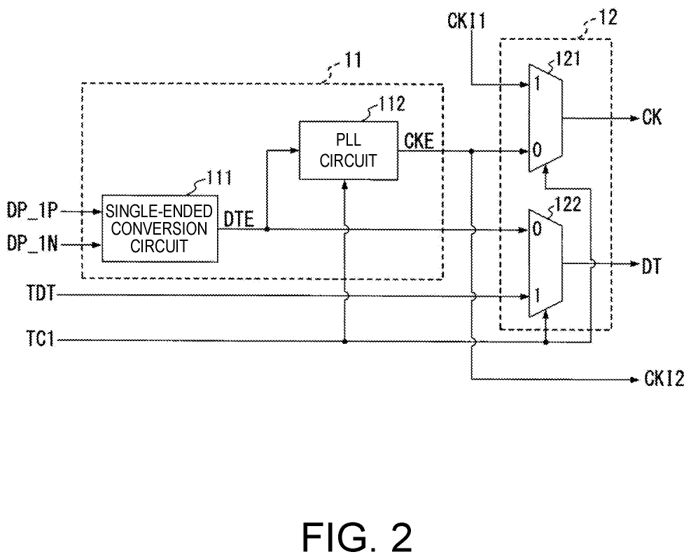

FIG. 2 is a block diagram showing an internal constitution of the receiver 11 and the selection circuit 12 included in the reception circuit block 10_1.

As shown in FIG. 2, the receiver 11 includes a single-ended conversion circuit 111 and a phase-locked loop (PLL) circuit 112.

The single-ended conversion circuit 111 receives the differential serial data signals (EDP_1P and EDP_1N) and restores the form of the differential signals to a form of a single-ended signal, namely, a single binary serial data signal. Further, the single-ended conversion circuit 111 supplies this restored serial data signal to the selection circuit 12 and the PLL circuit 112 as a serial data signal DTE.

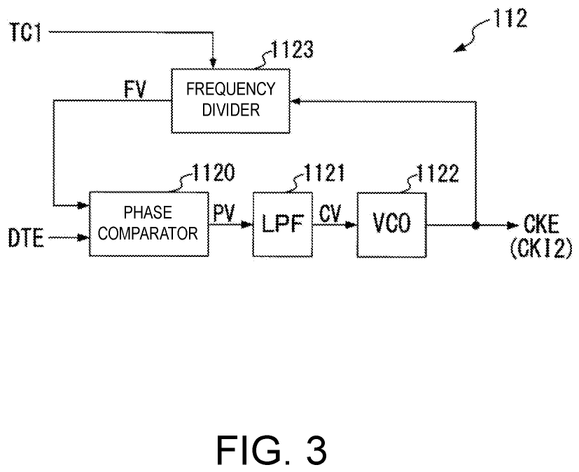

FIG. 3 is a block diagram showing an internal constitution of the PLL circuit 112.

As shown in FIG. 3, the PLL circuit 112 includes a phase comparator 1120, a loop filter (LPF) 1121, a voltage-controlled oscillator (VCO) 1122, and a frequency divider 1123.

The phase comparator 1120 detects a phase difference between the phase of a rising edge or a falling edge of the serial data signal DTE and the phase of a rising edge or a falling edge of a frequency-divided oscillation signal FV supplied from the frequency divider 1123. The phase comparator 1120 supplies a phase difference signal PV representing the detected phase difference to the loop filter 1121. The loop filter 1121 supplies the voltage of a low-frequency component in the phase difference signal PV to the VCO 1122 as a control voltage CV. The VCO 1122 supplies a signal having a frequency corresponding to the voltage value of the control voltage CV to the frequency divider 1123 and the selection circuit 12 as a clock signal CKE.

The frequency divider 1123 generates the frequency-divided oscillation signal FV by frequency-dividing the foregoing clock signal CKE at a frequency division ratio based on a test mode signal TC1 supplied from the test control circuit 20 and supplies it to the phase comparator 1120. For example, when the test mode signal TC1 indicates a normal operation, the frequency divider 1123 frequency-divides the clock signal CKE at a first frequency division ratio. Meanwhile, when the test mode signal TC1 indicates a test operation, the frequency divider 1123 frequency-divides the clock signal CKE at a second frequency division ratio higher than the first frequency division ratio.

Accordingly, the PLL circuit 112 generates the clock signal CKE having a frequency phase-synchronized with the timing of the edge of the serial data signal DTE and based on the test mode signal TC1.

That is, when the test mode signal TC1 indicates a normal operation, the PLL circuit 112 generates the clock signal CKE which has a predetermined first frequency, namely, which is phase-synchronized with the received serial data signal DTE and has the same frequency. Meanwhile, when the test mode signal TC1 indicates a test operation, the clock signal CKE having a second frequency higher than this first frequency is generated.

Further, the PLL circuit 112 supplies the generated clock signal CKE to the selection circuit 12 and supplies this generated clock signal CKE to the selection circuit 12 and the test control circuit 20 of the different reception circuit block 10_2 as a test clock signal CKI2.

As shown in FIG. 2, the selection circuit 12 includes a selector 121 performing selection of a clock signal, and a selector 122 performing selection of a data signal.

The selector 121 selects one of the clock signal CKE supplied from the PLL circuit 112 and a test clock signal CKI1 supplied from the reception circuit block 10_4 in accordance with the test mode signal TC1. That is, the selector 121 selects the clock signal CKE from the clock signals CKE and CKI1 when the test mode signal TC1 indicates a normal operation, whereas the test clock signal CKI1 is selected when the test mode signal TC1 indicates a test operation. Further, the selector 121 supplies the signal selected from the clock signals CKE and CKI1 to the S/P conversion circuit 13 as a clock signal CK.

The selector 122 selects one of the serial data signal DTE supplied from the single-ended conversion circuit 111 and a test serial data signal TDT supplied from the test control circuit 20 in accordance with the foregoing test mode signal TC1. That is, when the test mode signal TC1 indicates a normal operation, the selector 122 selects the serial data signal DTE from the serial data signal DTE and the test serial data signal TDT. Meanwhile, when the test mode signal TC1 indicates a test operation, the selector 122 selects the test serial data signal TDT. Further, the selector 122 supplies the signal selected from the serial data signal DTE and the test serial data signal TDT to the S/P conversion circuit 13 as a serial data signal DT.

The S/P conversion circuit 13 converts the serial data signal DT supplied from the selection circuit 12 into data in an 8-bit parallel form, for example, at a timing synchronized with the clock signal CK supplied from the selection circuit 12 and supplies this to the test control circuit 20 and the main signal processing circuit (not shown) as the reception data TD1.

Due to this constitution, when the test mode signal TC1 indicates a normal operation, the reception circuit block 10_1 first converts the received differential serial data signals (EDP_1P and EDP_1N) into a form of a binary single-ended signal and acquires it as the serial data signal DTE. Further, in the reception circuit block 10_1, the PLL circuit 112 generates the clock signal CKE based on the serial data signal DTE and the serial data signal DTE is converted into a parallel form at a timing synchronized with the clock signal CKE, thereby obtaining the reception data TD1. Meanwhile, when the test mode signal TC1 indicates a test operation, the reception circuit block 10_1 obtains the reception data TD1 by converting the test serial data signal TDT supplied from the test control circuit 20 into a parallel form at a timing synchronized with the test clock signal CKI2 supplied from the reception circuit block 10_4. Moreover, the reception circuit block 10_1 supplies the clock signal CKE generated by the PLL circuit 112 of itself to the selector 121 included in the selection circuit 12 of the reception circuit block 10_2, and the test control circuit as the test clock signal CKI2.

In a form similar to the foregoing reception circuit block 10_1, the reception circuit blocks 10_2 to 10_4 also respectively acquire the reception data TD2 to the reception data TD4 based on the differential serial data signals (EDP_2P and EDP_2N) to (EDP_4P and EDP_4N) which have been received respectively.

However, the reception circuit blocks 10_2 to 10_4 individually receive test mode signals TC2 to TC4 respectively from the test control circuit 20. Similar to the test mode signal TC1, each of the test mode signals TC2 to TC4 is also a signal for instructing a normal operation or a test operation.

In addition, the reception circuit block 10_2 supplies the clock signal CKE generated by the PLL circuit 112 of itself to the selector 121 of the selection circuit 12 of the reception circuit block 10_3 and the test control circuit 20 as a test clock signal CKI3. The reception circuit block 10_3 supplies the clock signal CKE generated by the PLL circuit 112 of itself to the selector 121 of the selection circuit 12 of the reception circuit block 10_4 and the test control circuit 20 as a test clock signal CKI4. Moreover, the reception circuit block 10_4 supplies the clock signal CKE generated by the PLL circuit 112 of itself to the selector 121 of the selection circuit 12 of the reception circuit block 10_1 and the test control circuit 20 as the test clock signal CKI1.

The test control circuit 20 performs a built-in self-test with respect to the S/P conversion circuit 13 of each of the reception circuit blocks 10_1 to 10_4 and outputs a test result signal TRSLT indicating the quality thereof.

The test control circuit 20 includes a test pattern circuit and an expected value circuit (neither is shown). The test pattern circuit is constituted of a test data generation circuit generating the test serial data signal TDT for confirming operation of the S/P conversion circuit 13 or a memory in which the test serial data signal TDT is stored in advance, and the like. The expected value circuit is constituted of an expected value generation circuit generating, as an expected value, an output signal which will be output from the S/P conversion circuit 13 when the test serial data signal TDT is input to the S/P conversion circuit 13 or a memory in which this expected value itself is stored in advance, and the like.

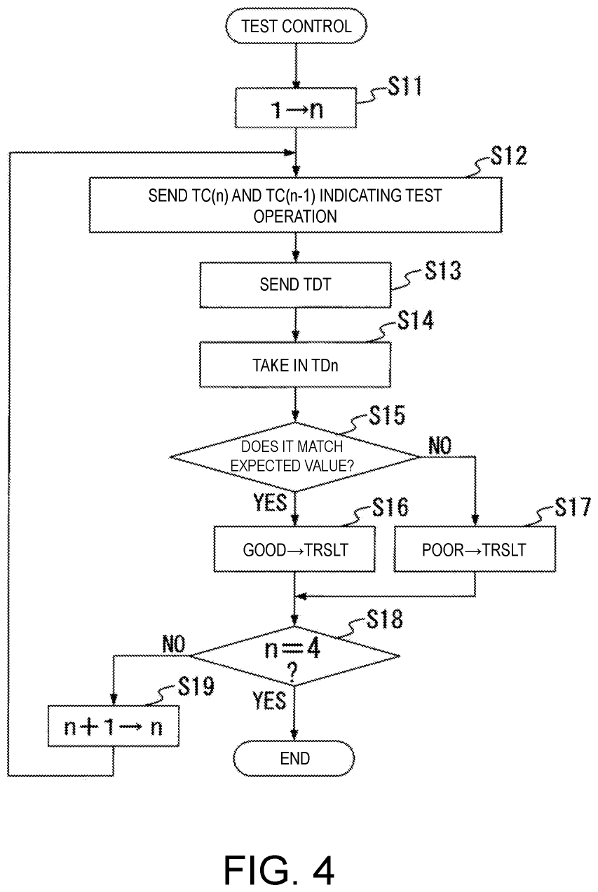

Hereinafter, a test of a semiconductor IC chip including the data reception circuit 100 shown in FIG. 1 performed before product shipment will be described along a test control flow shown in FIG. 4.

In performing the test, first, a semiconductor IC chip including the data reception circuit 100 is connected to an LSI tester. The LSI tester supplies a test signal TST prompting execution of a test to the semiconductor IC chip.

The test control circuit 20 performs a test with respect to the S/P conversion circuit 13 of each of the reception circuit blocks 10_1 to 10_4 along the test control flow shown in FIG. 4 in response to the test signal TST prompting execution of a test.

In FIG. 4, the test control circuit 20 first sets an initial value “1” as a reception circuit block number n for designating a reception circuit block to be tested (Step S11).

Next, the test control circuit 20 supplies test mode signals TC (n) and TC (n−1) indicating a test operation to nth and (n−1) th reception circuit blocks of the reception circuit blocks 10_1 to 10_4 (Step S12). Namely, in Step S12, the test control circuit 20 supplies the test mode signal TC (n) indicating a test operation to the reception circuit block 10_(n) and supplies the test mode signal TC (n−1) indicating a test operation to the reception circuit block 10_(n−1). However, when “n” is 1, in Step S12, the test control circuit 20 supplies the test mode signal TC1 indicating a test operation to the reception circuit block 10_1 and supplies the test mode signal TC4 indicating a test operation to the reception circuit block 10_4.

Through Step S12, the PLL circuit 112 of each of a pair of reception circuit blocks designated as the foregoing “n”^{th} among the reception circuit blocks 10_1 to 10_4 is in a state of generating the clock signal CKE having the second frequency higher than the first frequency during a normal operation. At this time, for example, the clock signal CKE generated by the PLL circuit 112 of the reception circuit block 10_(n−1) is supplied to the selection circuit 12 of the reception circuit block 10_(n) as a test clock signal CKI (n) and is supplied to the S/P conversion circuit 13 of the reception circuit block 10_(n) via this selection circuit 12. Namely, the clock signal CKE generated by the PLL circuit 112 of the reception circuit block 10_1 is supplied to the selection circuit 12 of the reception circuit block 10_2 as the test clock signal CKI2 and is supplied to the S/P conversion circuit 13 of the reception circuit block 10_2 via this selection circuit 12. In addition, the clock signal CKE generated by the PLL circuit 112 of the reception circuit block 10_2 is supplied to the selection circuit 12 of the reception circuit block 10_3 as the test clock signal CKI3 and is supplied to the S/P conversion circuit 13 of the reception circuit block 10_3 via this selection circuit 12. In addition, the clock signal CKE generated by the PLL circuit 112 of the reception circuit block 10_3 is supplied to the selection circuit 12 of the reception circuit block 10_4 as the test clock signal CKI4 and is supplied to the S/P conversion circuit 13 of the reception circuit block 10_4 via this selection circuit 12.

However, when “n” is 1, the clock signal CKE generated by the PLL circuit 112 of the reception circuit block 10_4 is supplied to the selection circuit 12 of the reception circuit block 10_1 as the test clock signal CKI1 and is supplied to the S/P conversion circuit 13 via this selection circuit 12.

Next, the test control circuit 20 supplies the test serial data signal TDT generated by the test data generation circuit to the reception circuit blocks 10_1 to 10_4 at a timing synchronized with a test clock signal CKI (n−1) (Step S13). Through Step S13, the test serial data signal TDT is supplied to the S/P conversion circuit 13 via the selection circuit 12 of the reception circuit block 10_(n). Thus, the S/P conversion circuit 13 of the reception circuit block 10_(n) supplies data of the test serial data signal TDT, which is converted into a parallel form at a timing synchronized with the test clock signal CKI (n−1) supplied from the reception circuit block 10_(n−1), to the test control circuit 20 as a reception data TD (n).

Here, the test control circuit 20 takes in the reception data TD (n) output from the reception circuit block 10_(n) as described above (Step S14) and judges whether or not this matches the foregoing expected value (Step S15).

In this Step S15, when it is judged that they match each other, the test control circuit 20 outputs the test result signal TRSLT indicating “good” to the LSI tester as an inspection result (Step S16). Meanwhile, when it is judged in Step S15 that they do not match each other, the test control circuit 20 outputs the test result signal TRSLT indicating “poor” to the LSI tester as an inspection result (Step S17).

After execution of Step S16 or S17, the test control circuit 20 judges whether or not the reception circuit block number n is the largest value “4” (Step S18). In Step S18, when it is judged that the reception circuit block number n is not the last number “4”, the test control circuit 20 sets a number obtained by adding “1” to the reception circuit block number n as a new reception circuit block number n (Step S19). After execution of Step S19, the test control circuit 20 returns to the foregoing Step S12 and executes the processing of Steps S12 to S19 described above again.

Here, for each of the reception circuit blocks 10_1 to 10_4, the test control circuit 20 sequentially outputs the test result signal TRSLT indicating whether or not the S/P conversion circuit 13 of this reception circuit block is a qualified product to the LSI tester by repeatedly executing the processing of Steps S14 to S19 until the reception circuit block number n becomes the last number “4”.

Hereinabove, as described in detail, in the data reception circuit 100, during a test operation, the frequency of a clock signal generated by the PLL circuit 112 included in each of the reception circuit blocks 10_1 to 10_4 is switched to a frequency higher than that during a normal operation. Further, in each of the reception circuit blocks 10_1 to 10_4, the quality of the S/P conversion circuit 13 is judged by operating the S/P conversion circuit 13 of itself using a clock signal generated by the PLL circuit 112 of a different reception circuit block other than that of itself.

According to this constitution, an operation test of the S/P conversion circuit 13 can be performed without mounting an oscillation circuit (including a PLL circuit) generating a clock signal having a frequency higher than the frequency that can be applied to the LSI tester simply for test purposes.

Thus, according to the disclosure, it is possible to curb increase in circuit size and perform a high-speed operation test for semiconductor IC chips before product shipment without depending on a frequency that can be applied to the LSI tester.

In the foregoing Example, the S/P conversion circuit 13 is subjected to a test. However, any signal processing circuit other than an S/P conversion circuit may be subjected to a test as long as it is a circuit operating in synchronization with the clock signal CKE.

In addition, in the foregoing Example, there are four circuit blocks to be tested, such as the reception circuit blocks 10_1 to 10_4. However, the number of circuit blocks to be tested is not limited to four, and there may be multiple such as two, five, or more circuit blocks.

In short, in order to test semiconductor IC chips including a plurality of reception circuit blocks (10_1 to 10_4) each of which performs predetermined signal processing (for example, S/P conversion) with respect to the individually received data signal (DTE), they need only include the following PLL circuit, a first selector, and a signal processing circuit as each of the plurality of reception circuit blocks.

The PLL circuit (112) generates the clock signals (CKE and CKI) phase-synchronized with the received data signal (DTE). The first selector (121) selects, based on the test mode signals (TC1 to TC4), one of the clock signal (CKI) generated by the PLL circuit (112) of a different reception circuit block other than the reception circuit block of itself of the plurality of reception circuit blocks and the clock signal (CKE) generated by the PLL circuit (112) of the reception circuit block of itself. The signal processing circuit (13) performs predetermined signal processing (for example, S/P conversion) in synchronization with the clock signal selected by the first selector.

Here, the PLL circuit (112) generates the clock signals (CKE and CKI) having the first frequency corresponding to the frequency of the data signal (DTE) received by the reception circuit block of itself when the test mode signals (TC1 to TC4) indicate a normal operation. Meanwhile, when the test mode signals indicate a test operation, the PLL circuit (112) generates the clock signals (CKE and CKI) having the second frequency higher than the first frequency. When the test mode signals indicate a normal operation, the first selector (121) selects the clock signal generated by the PLL circuit of the reception circuit block of itself and supplies it to the signal processing circuit (13). Meanwhile, when the test mode signals indicate a test operation, the first selector (121) selects the clock signal generated by the PLL circuit of a different reception circuit block other than that of itself and supplies it to the signal processing circuit (13).

Due to this constitution, during a test operation for a semiconductor IC chip (semiconductor device), the frequency of a clock signal generated by the PLL circuit included in each of the reception circuit blocks is switched to a frequency higher than that during a normal operation. Further, in each of the reception circuit blocks, the signal processing circuit of itself is operated in response to a clock signal generated by the PLL circuit of a different reception circuit block other than that of itself. Accordingly, a high-speed operation test can be performed with respect to the signal processing circuit using an internally generated clock signal without providing an oscillation circuit generating a clock signal having a frequency higher than the frequency that can be applied to the LSI tester simply for test purposes.

Thus, according to the disclosure, it is possible to curb increase in circuit size and perform a high-speed operation test for semiconductor devices before product shipment without depending on a frequency that can be applied to an LSI tester.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device comprising:
a plurality of reception circuit blocks, each individually receiving a data signal, performing predetermined signal processing for the received data signal, and receiving a test mode signal for instructing a normal operation or a test operation,
wherein each of the plurality of reception circuit blocks includes:
a phase-locked loop (PLL) circuit generating a clock signal phase-synchronized with a data signal received by itself,
a first selector selecting, based on the test mode signal, among the plurality of reception circuit blocks, one of the clock signal generated by the PLL circuit of a different reception circuit block other than a reception circuit block of itself and the clock signal generated by the PLL circuit of the reception circuit block of itself, and
a signal processing circuit performing the predetermined signal processing in synchronization with the clock signal selected by the first selector.

2. The semiconductor device according to claim 1,
wherein the PLL circuit generates the clock signal having a first frequency corresponding to a frequency of the data signal received by the reception circuit block of itself when the test mode signal indicates the normal operation, and generates the clock signal having a second frequency higher than the first frequency when the test mode signal indicates the test operation.

3. The semiconductor device according to claim 1,
wherein the first selector selects the clock signal generated by the PLL circuit of the reception circuit block of itself when the test mode signal indicates the normal operation, and selects the clock signal generated by the PLL circuit of the different reception circuit block when the test mode signal indicates the test operation.

4. The semiconductor device according to claim 2,
wherein the first selector selects the clock signal generated by the PLL circuit of the reception circuit block of itself when the test mode signal indicates the normal operation, and selects the clock signal generated by the PLL circuit of the different reception circuit block when the test mode signal indicates the test operation.

5. The semiconductor device according to claim 1 further comprising:
a test control circuit supplying, in response to a test signal prompting test execution, the test mode signal indicating the test operation and a predetermined test data signal to each of the plurality of reception circuit blocks,
wherein each of the plurality of reception circuit blocks further includes:
a second selector receiving the data signal received by the reception circuit block of itself and the test data signal supplied from the test control circuit, selecting and supplying the data signal received by the reception circuit block of itself to the signal processing circuit when the test mode signal indicates the normal operation, and selecting and supplying the test data signal to the signal processing circuit when the test mode signal indicates the test operation.

6. The semiconductor device according to claim 2 further comprising:
a test control circuit supplying, in response to a test signal prompting test execution, the test mode signal indicating the test operation and a predetermined test data signal to each of the plurality of reception circuit blocks,
wherein each of the plurality of reception circuit blocks further includes:
a second selector receiving the data signal received by the reception circuit block of itself and the test data signal supplied from the test control circuit, selecting and supplying the data signal received by the reception circuit block of itself to the signal processing circuit when the test mode signal indicates the normal operation, and selecting and supplying the test data signal to the signal processing circuit when the test mode signal indicates the test operation.

7. The semiconductor device according to claim 5,
wherein the test control circuit takes in an output signal output from the signal processing circuit of each of the plurality of reception circuit blocks when the test data signal is supplied to each of the plurality of reception circuit blocks, and judges a quality of each of the signal processing circuits depending on whether or not the output signal matches a predetermined expected value.

8. The semiconductor device according to claim 6,
wherein the test control circuit takes in an output signal output from the signal processing circuit of each of the plurality of reception circuit blocks when the test data signal is supplied to each of the plurality of reception circuit blocks, and judges a quality of each of the signal processing circuits depending on whether or not the output signal matches a predetermined expected value.

9. A test method for the semiconductor device according to claim 1, the test method comprising:
a step of supplying the test mode signal indicating the test operation to the PLL circuit of each of the plurality of reception circuit blocks and the first selector in response to a test signal prompting execution of a test;
a step of supplying a testing data signal to the signal processing circuit of each of the plurality of reception circuit blocks; and
a step of judging a quality by sequentially taking in output results output from the signal processing circuit of each of the plurality of reception circuit blocks and comparing the output results with an expected value.
